(19) United States
(12) Patent Application Publication
(10) Pub. No.: US 2026/0107759 A1
(43) Pub. Date: Apr. 16, 2026

(54) SEMICONDUCTOR DEVICE WITH AIR GAP AND METHOD OF MANUFACTURING THE SEMICONDUCTOR DEVICE

(71) Applicant: TAIWAN SEMICONDUCTOR MANUFACTURING COMPANY, LTD., Hsinchu (TW)

(72) Inventors: Hsi-Wen TIEN, Hsinchu (TW); Chih Wei LU, Hsinchu (TW); Wei-Hao LIAO, Hsinchu (TW); Hsin-Chieh YAO, Hsinchu (TW); Hwei-Jay CHU, Hsinchu (TW); Yu-Teng DAI, Hsinchu (TW); Wei Chih WANG, Hsinchu (TW); Cheng-Hao CHEN, Hsinchu (TW)

(73) Assignee: TAIWAN SEMICONDUCTOR MANUFACTURING COMPANY, LTD., Hsinchu (TW)

(21) Appl. No.: 18/916,250

(22) Filed: Oct. 15, 2024

(51) Int. Cl. H01L 23/528; H01L 21/02; H01L 21/311; H01L 21/762

(52) U.S. Cl. CPC H10W 20/435; H10P 14/683; H10P 50/287; H10W 10/014; H10W 10/17

(57) ABSTRACT

A method includes patterning a metal layer on a substrate to form two metal lines spaced apart from each other by a recess, forming a directed self-assembly (DSA) segment in the recess, wherein the DSA segment includes block co-polymer (BCP), performing a phase separation process on the DSA segment to cause two components of the BCP to separate from each other to form a first polymer block and a second polymer block that are aligned next to each other in the recess, and removing the second polymer block to form an air gap that is bordered by the first polymer block and that is located between the metal lines.

### BACKGROUND

With the rapid growth of the semiconductor integrated circuit industry, functional density, i.e., the number of functioning devices per chip area, has increased and dimensions of components, such as transistors and interconnects, have reduced. Interconnects are conductive structures, such as traces or metal lines, that electrically connect two or more elements to form circuits. As interconnects are scaled down, pitches between the conductive structures become smaller, resulting in higher capacity which would adversely influence performance of a device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart that illustrates steps of a method in accordance with some embodiments.

FIGS. 2A-2C, 3A-3C, 4A-4C, 5A-5C, 6A-6C, 7A-7C, 8A-8C, 9A-9C, 10A-10C, and 11A-11C are sectional views and top views of intermediate stages of the method of FIG. 2 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “top,” “bottom,” “underneath,” “adjacent,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

An interconnect layer includes metal lines and dielectric material for insulating the metal lines, and may be formed using a metal patterning process on a metal substrate or a damascene process. The dielectric material is selected to have a lower relative permittivity (i.e., low-k) dielectric material to reduce interference, noise and parasitic capacitance between the metal lines. Since air has the relative permittivity lower than those of common low-k dielectric materials, efforts are made to introduce air into the dielectric material when forming the interconnect layer.

Directed self-assembly (DSA) is a type of directed assembly process which utilizes a block co-polymer (BCP) to create lines, hole patterns and space, facilitating a more accurate control of feature shapes. In a DSA process, a BCP coating including blocks of different polymerized monomers, for example, the polystyrene-block-polymethylmethacrylate (PS-b-PMMA), is first dispensed. A BCP segregation process, such as an annealing step, is then performed to cause a phase separation in the BCP coating so that the PS and PMAA are separated into parallel strips. The PMAA strips are finally removed and the PS strips remain, so as to form air gaps between the PS strips.

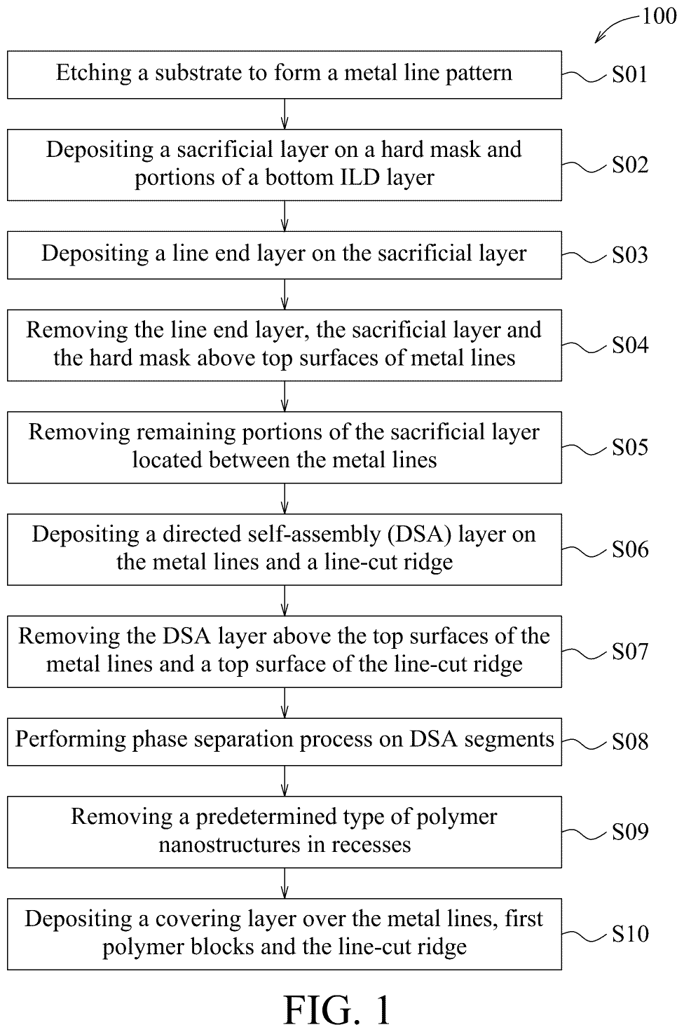

FIG. 1 is a flow diagram illustrating a method 100 of manufacturing a semiconductor device in accordance with some embodiments of this disclosure. The method 100 includes steps S01 to S10, and is discussed in detail below with reference to a semiconductor device 200 in FIGS. NA, NB, NC, where N indicates an integer starts from 2 to 11, illustrating some intermediate stages of the method 100 in accordance with some embodiments. FIGS. NA illustrate cross-sectional views of the semiconductor device 200 in a cross-line direction X, FIGS. NB illustrate cross-sectional views of the semiconductor device 200 in an along-line direction Y that is substantially perpendicular to the cross-line direction X, and FIGS. NC illustrate top views of the semiconductor device 200. Some portions may be omitted in the aforementioned figures for the sake of brevity. Additional steps can be provided before, after or during the method 100, and some of the steps described herein may be replaced by other steps or be eliminated. Similarly, further additional features may be present in the semiconductor device 200, and/or features present may be replaced or eliminated in additional embodiments.

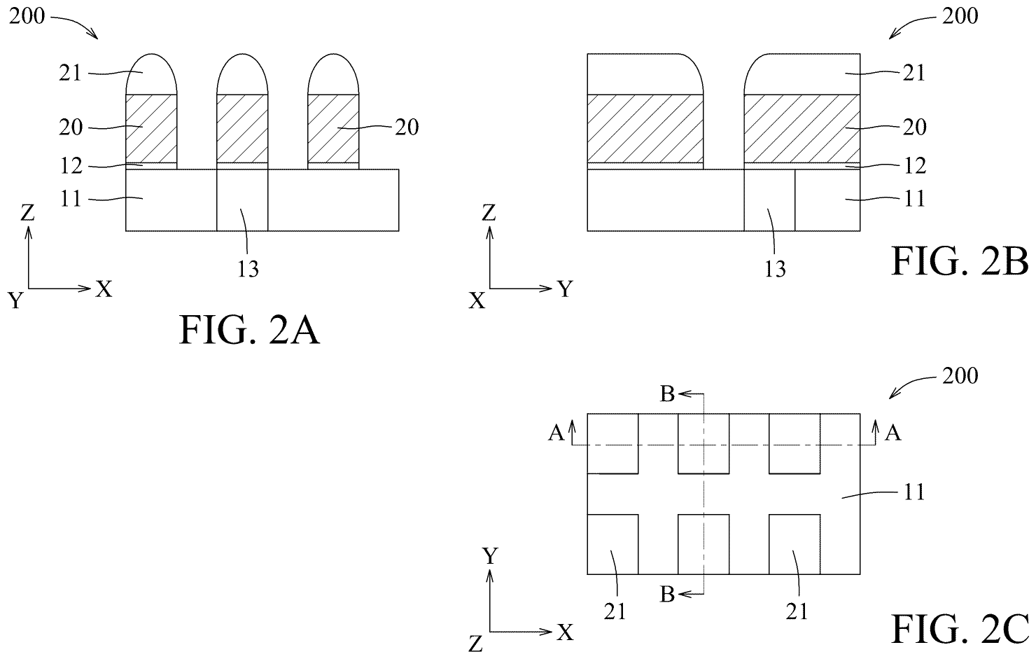

Referring to FIG. 1 and the example illustrated in FIGS. 2A to 2C, the method 100 begins at step S01, where a substrate 10 is etched to form a metal line pattern. The substrate includes a bottom interlayer dielectric (ILD) layer 11, a glue layer 12 deposited on the bottom ILD layer 11 and a metal layer deposited on the glue layer 12. In this case, the substrate 10 is a metal substrate.

In some embodiments, the bottom ILD layer 11 includes a low-k dielectric, such as a silicon oxide (SiO2), silicon nitride (SiN), silicon oxynitride (SiON), silicon carbide (SiC), other suitable materials or combinations thereof. The bottom ILD layer may be deposited by thermal oxidation chemical vapor deposition (CVD), physical vapor deposition (PVD), thermal oxidation, other suitable deposition processes or combinations thereof. The bottom ILD layer 11 is formed with a via feature 13 that includes Cu, Al, Ag, Ti, W, Mn, Zr, Ru, Mo, Mo, TiN, TiAlN, TaN, TaC, TaCN, TaSiN, WN, other suitable material or combinations thereof. The via feature 13 may be formed in the bottom ILD layer 11 by using one or more damascene processes. The glue layer 12 includes Ta, Co, Cu, Ru, W, Zr, TaN, TiN, graphene, other suitable materials or combinations thereof. The glue layer 12 is deposited using PVD, CVD, atomic layer deposition (ALD), other suitable processes/or combinations thereof under a temperature ranging from about 80 degree Celsius (° C.) to about 400° C. A thickness of the glue layer 12 ranges from about 5 angstroms to about 200 angstroms. The metal layer includes Al, Cu, Co, W, Ru, Zr, other suitable materials or combinations thereof. The metal layer is deposited using ALD, PVD, CVD, electroless deposition (ELD), other suitable processes or combinations thereof under a temperature ranging from about 70° C. to about 400° C. A thickness of the metal layer ranges from about 20 angstroms to about 700 angstroms.

To etch the metal layer of the substrate 10, a hard mask 21 is first formed over the metal layer. In some embodiments, the hard mask 21 includes TiN, TiO, TiON, W, WC, HfO, ZrO, ZnO, TiZrO, SiC, SiO2, SiOC, SiN, SiCN, SiON, SiOCN, AlOx, AlON, other suitable materials or combinations thereof. The hard mask 21 is formed under a temperature ranging about 50° C. to about 400° C., and has a thickness ranging from about 30 angstroms to about 500 angstroms. The hard mask 21 has a plurality of openings, and portions of the metal layer are exposed through the openings. The metal layer is then etched through the openings of the hard mask 21 using ion beam etching (IBE), reactive ion etching (RIE), other suitable processes or a combination thereof. In some embodiments, when IBE is adopted, IBE etching gases include He, Ne, Ar, Kr, Xe, other suitable gases or combinations thereof, an IBE etching angle ranges from about 0 degrees to about 70 degrees, and an IBE power ranges from about 50 watts to about 3000 watts. In some embodiments, when RIE is adopted, an inductively coupled plasma (ICP) RIE etcher or a capacitively coupled plasma (CCP) RIE etcher is used to realize etching of the metal layer, RIE etch gases include CH3OH, C2H5OH, CH4, CH3F, CH2F2, CHF3, C4F8, C4F6, CF4, H2, HBr, CO, CO2, O2, BCl3, Cl2, N2, He, Ne, Ar, other suitable gases or combinations thereof, a pressure for etching ranges from about 0.5 millitorr to about 100 millitorr, a temperature for etching ranges from about 15° C. to about 120° C., an etching power ranges from about 150 watts to about 3000 watts, and a bias voltages ranges from about 0 volts to about 2000 volts. After the metal layer is etched, the exposed portions of the metal layer (i.e., corresponding in position to the openings of the hard mask 21) are removed so as to form a plurality of metal lines 20 that are substantially parallel to one another and that constitute the metal line pattern. It is noted that portions of the glue layer 12 underneath the exposed portions of the metal layer are also removed in the etching process, so that portions of the bottom ILD layer 11 underneath the portions of the glue layer 12 are exposed. It is noted that in the example shown in FIG. 2C, the metal lines 20 which are covered by the hard mask 21 extend in the along-line direction Y, and each are cut in the cross-line direction X and are thus divided into metal line segments. The via feature 13 formed in the bottom ILD layer 11 may be aligned with one or more of the metal lines 20 in a top-bottom direction Z.

In some embodiments, in addition to the aforementioned components, the substrate 10 further includes an elementary semiconductor, such as silicon and germanium, a compound semiconductor, such as silicon carbide, gallium arsenic, indium arsenide, and indium phosphide, an alloy semiconductor such as silicon germanium, silicon germanium carbide, gallium arsenic phosphide, and gallium indium phosphide. In some embodiments, the substrate 10 further includes an epitaxial layer. For example, the substrate 10 may have an epitaxial layer overlying a bulk semiconductor. Furthermore, the substrate 10 may include a semiconductor-on-insulator (SOI) structure. For example, the substrate 10 may include a buried oxide (BOX) layer formed by a process such as separation by implanted oxygen (SIMOX) or other suitable technique, such as wafer bonding and grinding.

The substrate 10 may also include various p-type doped regions and/or n-type doped regions, implemented by a process such as ion implantation and/or diffusion. Those doped regions include n-well, p-well, lightly doped region (LDD) and various channel doping profiles configured to form various integrated circuit (IC) devices. The substrate 10 may also include various isolation regions. The isolation regions separate various device regions in the substrate 10. The isolation regions include different structures formed by using different processing technologies. For example, the isolation region may include shallow trench isolation (STI) regions. The substrate 10 may include gate stacks formed by dielectric layers and electrode layers. The substrate 10 may also include source/drain (S/D) features, which include germanium, silicon, gallium arsenide, aluminum gallium arsenide, silicon germanium, gallium arsenide phosphide, gallium antimony, indium antimony, indium gallium arsenide, indium arsenide, or other suitable materials.

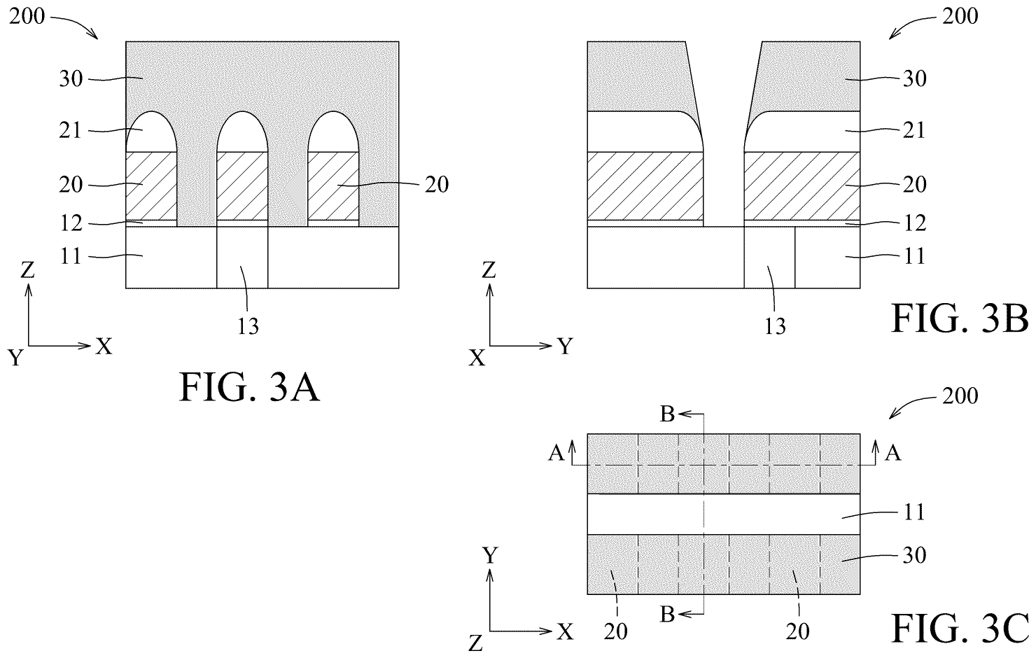

Referring to FIG. 1 and the example illustrated in FIGS. 3A to 3C, the method 100 proceeds to step S02, where a sacrificial layer 30 is deposited on the hard mask 21 and the portions of the bottom ILD layer 11. The sacrificial layer 30 is then etched to form a pattern that has a gap which encompasses locations where the metal lines 20 are cut, so that a portion of the bottom ILD layer 11 is exposed through the gap. In some embodiments, the sacrificial layer 30 includes SiC, SiOC, SiCN, SiOCN, SiO2, SiN, SiON, other suitable materials (e.g., a carbon-based material) or combinations thereof. The sacrificial layer 30 is deposited using spin-on coating, CVD, ALD, PVD, other suitable processes or combinations thereof under a temperature ranging from about 50° C. to about 400° C. A thickness of the sacrificial layer 30 ranges from about 30 angstroms to about 800 angstroms.

In some embodiments, the sacrificial layer 30 is etched through an opening of an etching mask (not shown) using RIE, other suitable processes or a combination thereof. In performing RIE, an ICP RIE etcher or a CCP RIE etcher is used to realize etching of the sacrificial layer, RIE etch gases include CH4, CH3F, CH2F2, CHF3, C4F8, C4F6, CF4, H2, HBr, CO, CO2, O2, BCl3, Cl2, N2, He, Ne, Ar, other suitable gases or combinations thereof, a pressure for etching ranges from about 0.2 millitorr to about 120 millitorr, a temperature for etching ranges from about 0° C. to about 100° C., an etching power ranges from about 50 watts to about 3000 watts, and a bias voltages ranges from about 0 volts to about 1200 volts.

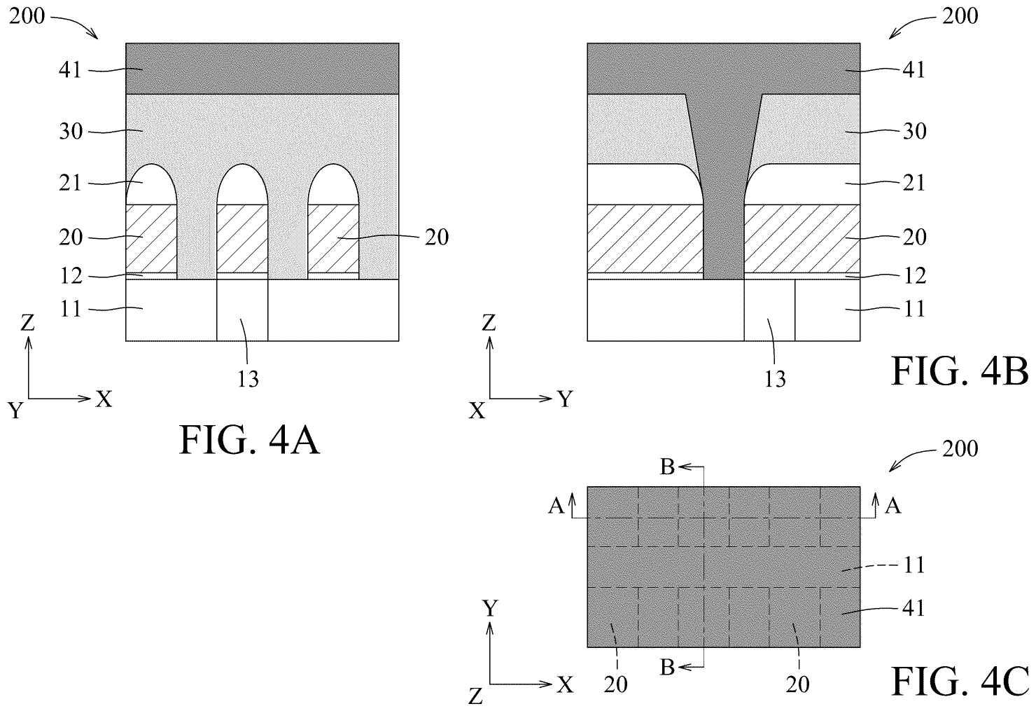

Referring to FIG. 1 and the example illustrated in FIGS. 4A to 4C, the method 100 proceeds to step S03, where a line end layer 41 is deposited on the sacrificial layer 30 and is filled into the gap of the sacrificial layer 30 so as to be disposed on the exposed portion of the bottom ILD layer 11. In some embodiments, the line end layer 30 is non-conductive, and includes a low-k dielectric material, such as SiO2, SiOC, other suitable dielectric or combinations thereof. The line end layer 30 is deposited using PVD, CVD, ALD, other suitable processes or combinations thereof.

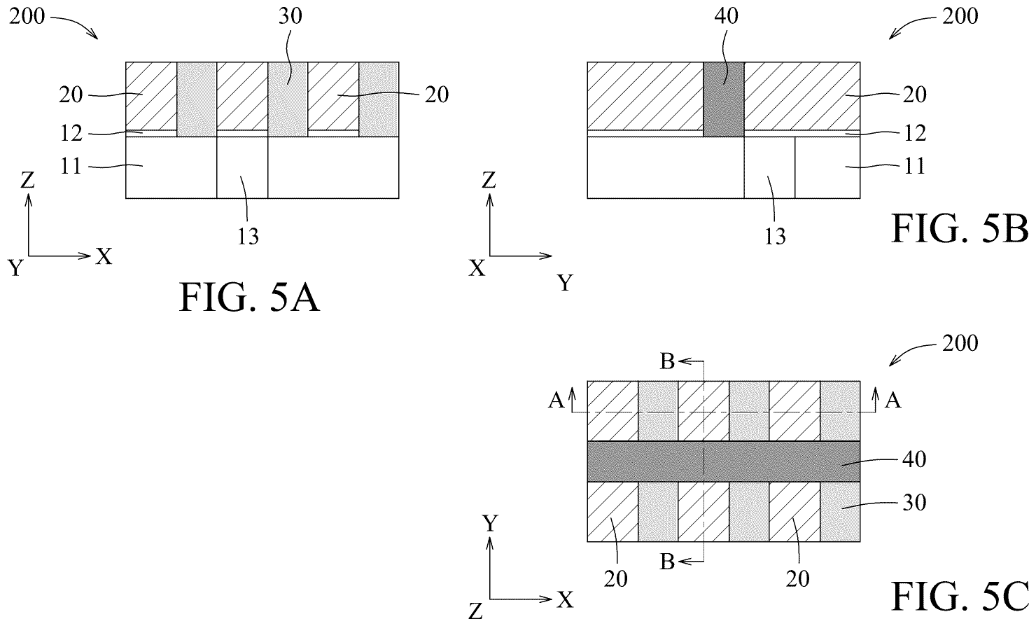

Referring to FIG. 1 and the example illustrated in FIGS. 5A to 5C, the method 100 proceeds to step S04, where the line end layer 41, the sacrificial layer 30 and the hard mask 21 (see FIG. 4B) above top surfaces of the metal lines 20 are removed, so that a portion of the line end layer 41 left in the gap of the sacrificial layer 30 remains, and portions of the sacrificial layer 30 located between the metal lines 20 remain and extend in the along-line direction Y. The remaining portion of the line end layer 41 forms a line-cut ridge 40 (also known as a line-end) which extends in the cross-line direction X and separate, for each of the metal lines 20, the metal line segments from each other in the along-line direction Y. In some embodiments, the removal of the line end layer 41, the sacrificial layer 30 and the hard mask 21 above the top surfaces of the metal lines 20 is implemented using an etching back process, such as dry etching, wet etching, or chemical-mechanical planarization (CMP).

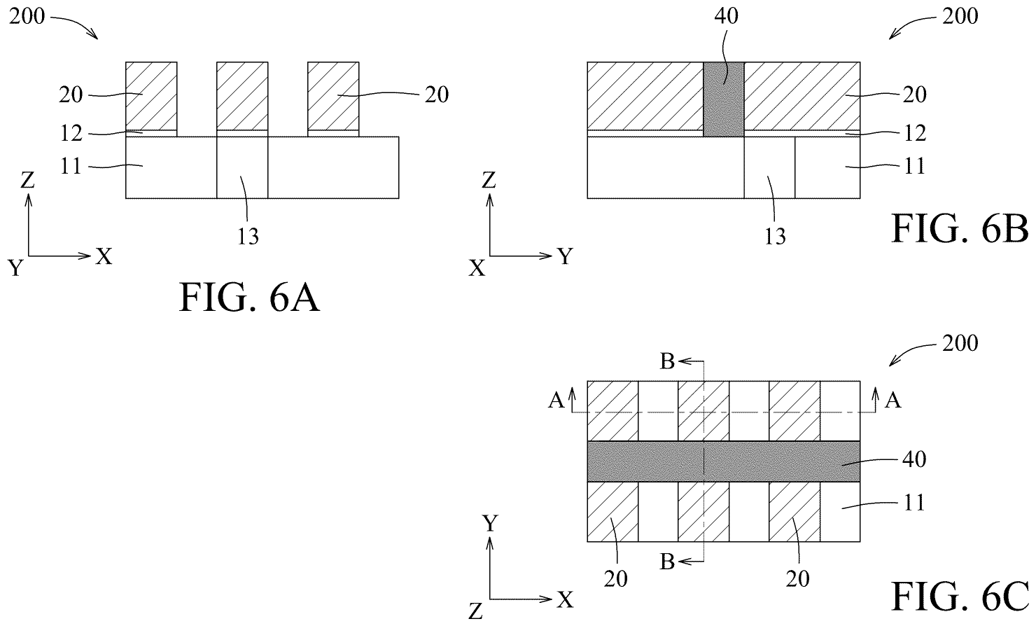

Referring to FIG. 1 and the example illustrated in FIGS. 6A to 6C, the method 100 proceeds to step S05, where the remaining portions of the sacrificial layer 30 located between the metal lines 20 are removed to form a plurality of recesses that are bordered by sidewalls of the metal lines 20 and the line-cut ridge 40 and that extend in the along-line direction Y. The portions of the bottom ILD layer 11 which are previously covered by the remaining portions of the sacrificial layer are exposed through the recesses. In some embodiments, since an etching directionality for removing the remaining portions of the sacrificial layer does not need to be considered, aside from RIE, thermal decomposition or other suitable processes may be adopted for removing the remaining portions.

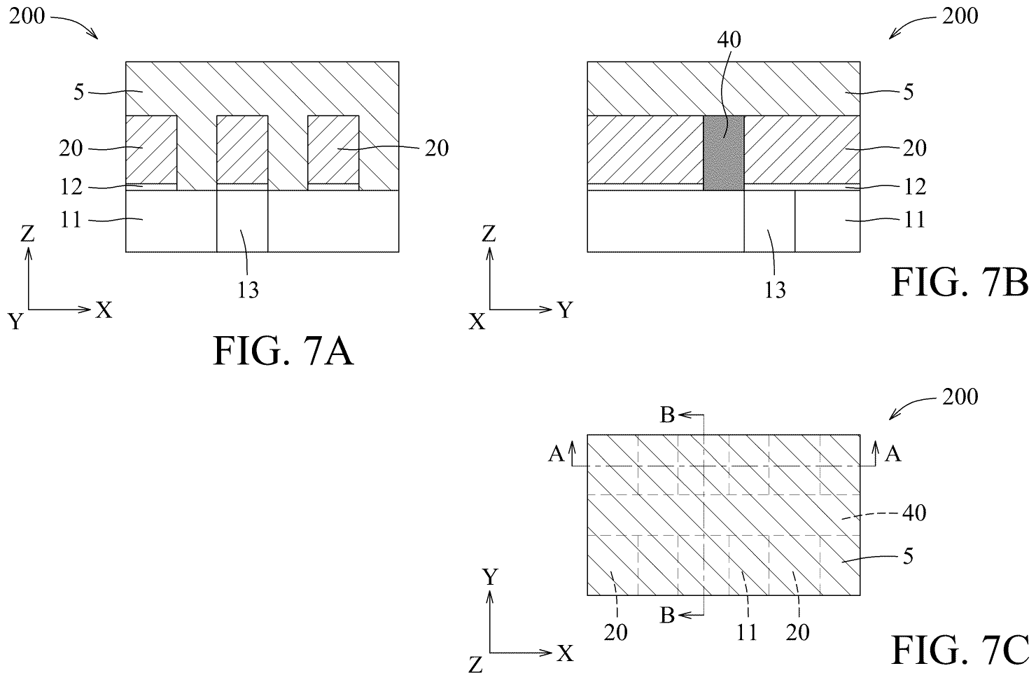

Referring to FIG. 1 and the example illustrated in FIGS. 7A to 7C, the method 100 proceeds to step S06, where a directed self-assembly (DSA) layer 5 is deposited on the metal lines 20 and the line-cut ridge 40, and fills into the recesses between the metal lines 20 so as to be disposed on the exposed portions of the bottom ILD layer 11.

The DSA layer 5 includes a block co-polymer (BCP) that has long-chain molecules comprised of at least two different main components which can assemble themselves into highly ordered structures under certain conditions, such as when they are exposed to an elevated temperature. In some embodiments, the DSA layer 5 may include polystyrene-block-polymethylmethacrylate (PS-b-PMMA), polyethyleneoxide block-polyisoprene (PEO-b-PI), polyethyleneoxide-block polybutadiene (PEO-b-PBD), polyethyleneoxide-block polystyrene (PEO-b-PS), polyethyleneoxide-block polymethylmethacrylate (PEO-b-PMMA), polyethyleneoxide-block-polyethylethylene (PEO-b-PEE), polystyrene-block-polyvinylpyridine (PS-b-PVP), polystyrene-block-polyisoprene (PS-b-PI), polystyrene-block polybutadiene (PS-b-PBD), polystyrene-block-polyferroce nyldimethylsilane (PS-b-PFS), polybutadiene-block polyvinylpyridine (PBD-b-PVP), polyisoprene block-polymethylmethacrylate (PI-b-PMMA), other suitable materials or combinations thereof. The DSA layer 5 may be deposited by spin-on coating, spraying, dip coating, other suitable deposition processes or combinations thereof. In this example of FIGS. 7A to 7C, the DSA layer 5 includes a bi-block polymer PS-b-PMMA, and is deposited using spin-on coating.

In some embodiments, prior to deposition of the DSA layer 5, a neutral layer (not shown) is first deposited over the exposed portions of the bottom ILD layer 11 in the recesses to enhance subsequent formation of the DSA layer 5 by modifying a surface condition of the exposed portions of the bottom ILD layer 11 in the recesses. The neutral layer includes materials having a surface energy that is in the middle of two main components of the DSA layer 5. For example, the neutral layer may include silicon oxide or spin-on-glass (SOG). In some embodiments, the neutral layer may be deposited using spin-on coating, CVD, ALD, other suitable deposition processes or combinations thereof.

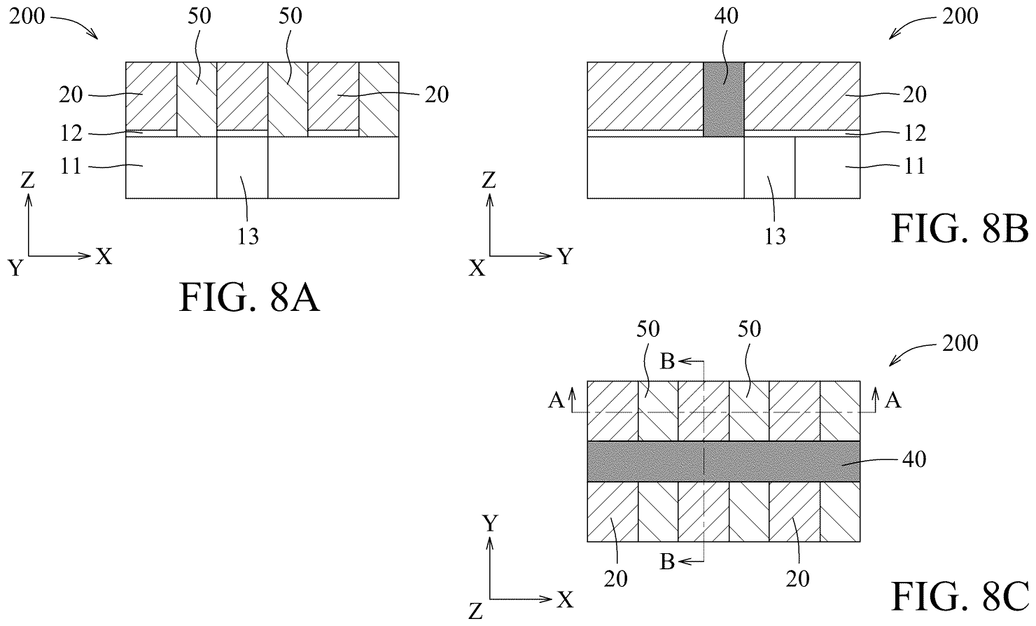

Referring to FIG. 1 and the example illustrated in FIGS. 8A to 8C, the method 100 proceeds to step S07, where the DSA layer 5 (see FIG. 7B) above the top surfaces of the metal lines 20 and a top surface of the line-cut ridge 40 is removed, so that portions of the DSA layer 5 located in the recesses between the metal lines 20 remain, so as to form a plurality of DSA segments 50 in the respective recesses. In some embodiments, the removal of the DSA layer 5 above the top surfaces of the metal lines 20 and the line-cut ridge 40 is implemented using an etching back process, such as dry etching, wet etching, or CMP.

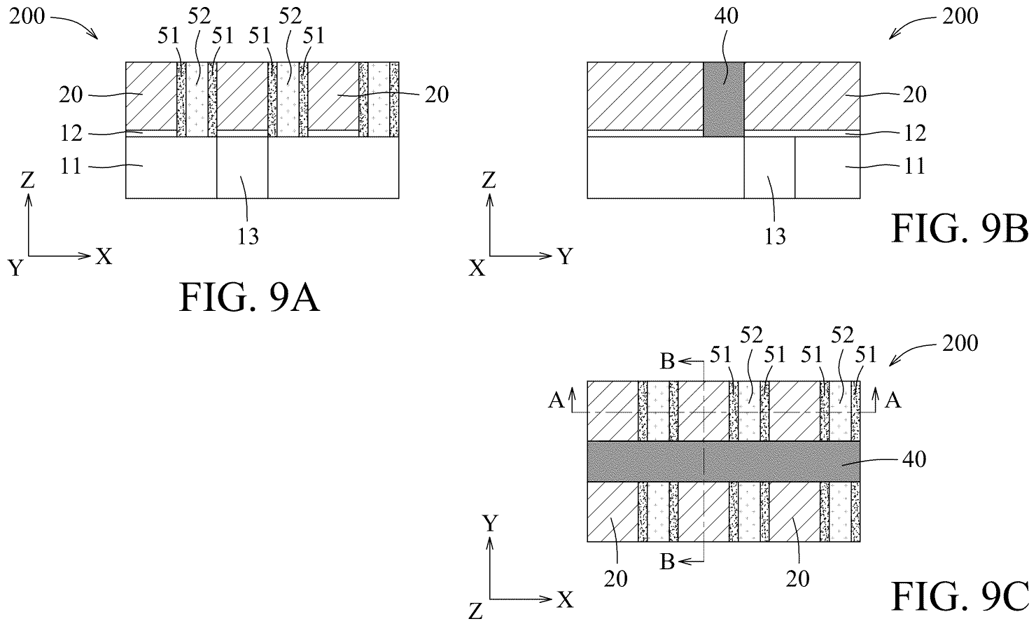

Referring to FIG. 1 and the example illustrated in FIGS. 9A to 9C, the method 100 proceeds to step S08, where a phase separation process is performed on the DSA segments 50 (see FIG. 8A) in the plurality of recesses between the metal lines 20 to cause, for each of the DSA segments 50, the two main components in the DSA segment 50 to separate from each other. In some embodiments, when the phase separation process is performed on the DSA segments 50, each of the DSA segments 50 forms two types of highly ordered self-assembling polymer nanostructures, i.e., a first polymer block 51 and a second polymer block 52, arranged as a lamellar layer in the along-line direction Y. The first polymer block 51 and the second polymer block 52 are aligned next to each other in a repeating periodical pattern in the cross-line direction X. In the example of FIGS. 9A to 9C, an elevated-temperature annealing is applied to the DSA segments 50 to form the highly ordered periodic polymer nanostructures in the recesses. For example, the annealing temperature may range from about 80° C. to about 320° C., with an annealing duration ranging from about 0.5 minutes to about 2.5 hours.

In alternative embodiments, the phase separation process is implemented by treating the DSA segments with a chemical. The treating chemical includes toluene (sometimes known as methylbenzene), which is a water-insoluble liquid. The DSA segments 50 may be treated by, for example, submerging the DSA segments 50 in the treating chemical, spraying the treating chemical on the DSA segments 50, or the like. In some embodiments, the treatment is performed at room temperature (for example, ranging from about 18° C. to about 25° C.). Higher temperatures may also be used to accelerate the phase separation process. The treating time may be in the range from about 0.5 minute to about 35 minutes.

In alternative embodiments, the phase separation process is implemented by treating the DSA segments 50 with an Ultra-Violet (UV) light. The UV light has a wavelength ranging from about 180 nanometers to about 400 nanometers, and the treatment time may range from about 5 seconds to about 60 minutes.

The first polymer block 51 and the second polymer block 52 have a first width and a second width in the cross-line direction X, respectively, and the first width and the second width are determined by the material property of the DSA layer 5, such as radius of gyration of the polymer chain, molecular weight and interfacial tension. In some embodiments, each of the first width and the second width ranges from about 5 nanometers to about 50 nanometers. In another embodiment, each of the first width and the second width ranges from about 10 nanometers to about 30 nanometers. In some embodiments, the DSA segments 50 including PS-b-PMMA are annealed and forms the first polymer blocks 51 of PS, and the second polymer blocks 52 of PMAA in a periodical repeating pattern in the cross-line direction X within the recesses. In the example of FIGS. 9A and 9C, for each of the DSA segments 50, the BCP in the respective one of the recesses forms two first polymer blocks 51 of PS, on the sidewalls of the metal lines 20 bordering the recess and one second polymer block 52 of PMAA, sandwiched between the two first polymer blocks 51 of PS. However, this disclosure is not limited to such, and in alternative embodiments, the BCP in each of the recesses, after the phase separation process, may form two second polymer blocks of PMAA on the sidewalls of the metal lines bordering the recess and one first polymer block of PS sandwiched between the two second polymer blocks of PMAA.

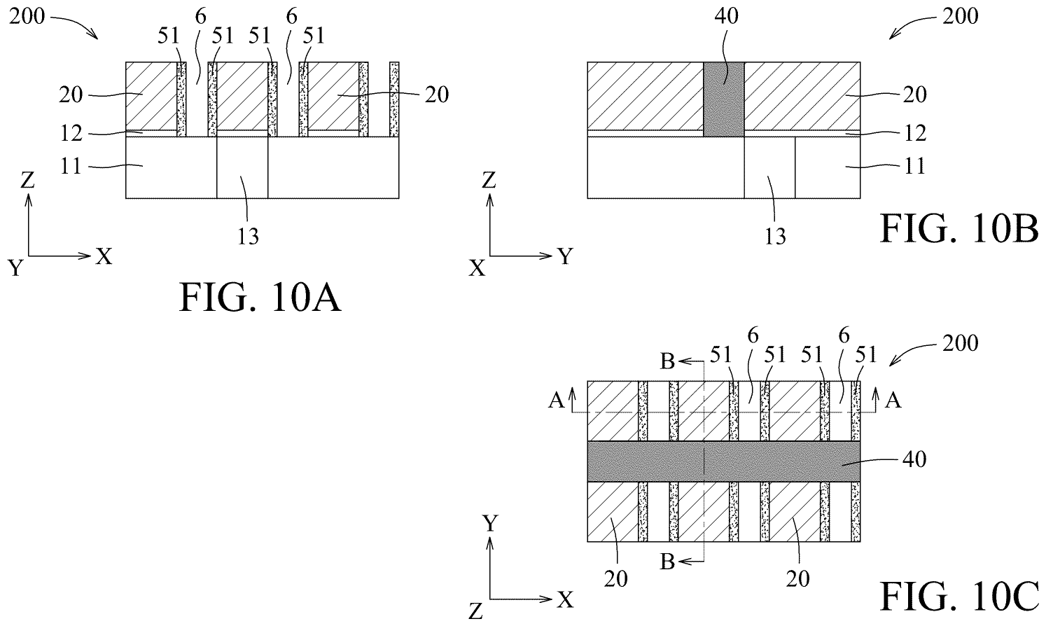

Referring to FIG. 1 and the example illustrated in FIGS. 10A to 10C, the method 100 proceeds to step S09, where a predetermined type of polymer nanostructures in the plurality of recesses, such as the second polymer blocks 52 (see FIG. 9A), is removed. In some embodiments, the second polymer blocks 52 are selectively decomposed, and the first polymer blocks 51 remain in the recesses. The selective decomposition includes dry etching, wet etching, ashing, other suitable etching processes or combinations thereof. In some embodiments, the removal process may include the use of a solvent such as acetone, benzene, chloroform, methylene chloride, and/or other suitable solvent. In this example, the second polymer blocks 52 of PMMA are decomposed through dry etching, wherein oxygen, carbon oxide, and/or the like are used as etching gases. In addition, some gases such as CxFy, may be used to protect the profile of the remaining first polymer blocks 51 of PS. In some embodiments, the second polymer blocks 52 of PMMA are etched through wet etching, for example, using acetic acid (also known as ethanoic acid, with the formula CHCOOH).

Since the second polymer blocks 52 of PMMA may have a high etching selectivity with respect to the first polymer blocks 51 of PS, as shown in FIGS. 10A and 10C, the second polymer blocks 52 of PMMA are selectively etched away to leave the first polymer blocks 51 of PS remaining. As a result, in each of the recesses, the remaining first polymer blocks 51 of PS are spaced apart from each other by spacing previously occupied by the second polymer block 52 of PMMA to form an air gap 6 between the remaining first polymer blocks 51 of PS, and thus between adjacent two of the metal lines 20. In some embodiments, a spacing between the remaining first polymer blocks 51 of PS (i.e., a pitch of the air gap 6) ranges from about 5 nanometers to about 50 nanometers. In this example, the pitch ranges from about 10 nanometers to about 30 nanometers. In each of the recesses, the remaining first polymer blocks 51 and the air gap 6 cooperatively form a dielectric structure that separates the adjacent two of the metal lines 20 from each other, and electrically isolates the adjacent two of the metal lines 20. In some embodiments, the metal lines 20, the line-cut ridge 40 and the dielectric structures form an interconnect layer.

In the aforesaid alternative embodiments where the two second polymer blocks of PMAA, are formed on the sidewalls of the metal lines and the first polymer block of PS, is sandwiched between the two second polymer blocks, the first polymer block of PS rather than second polymer blocks of PMAA is etched, and the second polymer blocks are left after the etching step to form the air gap therebetween.

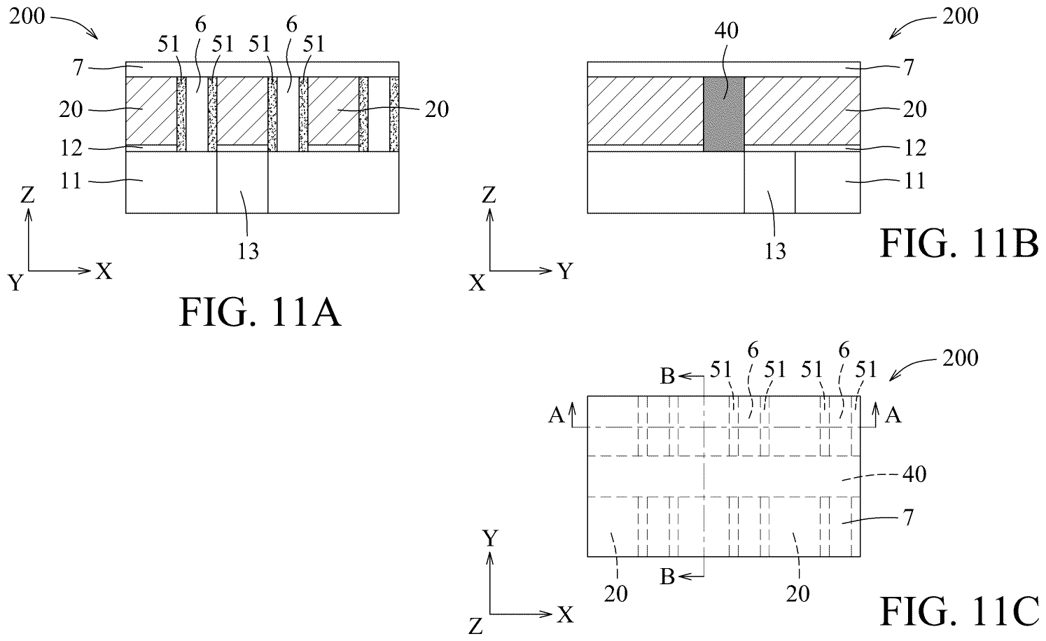

Referring to FIG. 1 and the example illustrated in FIGS. 11A to 11C, the method 100 proceeds to step S10, where a covering layer 7 related to a following process is deposited over the metal lines 20, the first polymer blocks 51 and the line-cut ridge 40, and covers openings of the air gaps 6 in the respective recesses. In some embodiments, the following process is the formation of another interconnect layer over the interconnect layer composed of the metal lines 20, the dielectric structures (i.e., the first polymer blocks 51 and the air gaps 6) and the line-cut ridge 40, and the covering layer 7 is another ILD layer that includes a low-k dielectric, such as a silicon oxide (SiO₂), silicon nitride (SiN), silicon oxynitride (SiON), silicon carbide (SiC), other suitable materials or combinations thereof. The covering layer 7 may be deposited by CVD, PVD, thermal oxidation, other suitable deposition processes or combinations thereof.

In this way, a more stable dielectric structure including the air gaps 6 may be formed between the metal lines 20. The air gaps 6 reduce the relative permittivity of the overall semiconductor device 200, and thus may alleviate the issue caused by using ultra-low-k (e.g., k less than about 2.5) but fragile or sensitive dielectric materials. By reducing the relative permittivity of the dielectric structure for separating the metal lines 20, parasitic effects between the metal lines 20 are reduced. Because a metal line can be modeled as a resistor (R) and a capacitor (C), these parasitic effects may be referred to as RC effects. Typically, a metal line may increase the effective capacitance of an adjacent metal line. In some embodiments, decreasing the relative permittivity (and thereby improving the insulating qualities) of the dielectric structure separating the metal lines 20 reduces this effective capacitance. Accordingly, the air gaps 6 reduce the effective capacitance and thereby the energy required to drive a signal through one of the metal lines 20. This allows the use of lower powered devices. The advantages also extend beyond RC effects. In one example, by reducing relative permittivity, the air gaps 6 may reduce parasitic noise that may cause signal errors. In a further example, the reduced relative permittivity due to air gaps 6 allows for closer metal line spacings and reduced overall circuit size. It is noted that these advantages are merely exemplary, and skilled people in the relevant art would recognize further advantages of the principles of the present disclosure. However, no particular advantage is necessary or required for any particular embodiment.

Moreover, since the DSA utilized to realize the patterning process for forming air gaps involves a single direction, i.e., the lamellar layer including the first polymer block and second polymer block extending in the along-line direction Y, fewer parameters related to the step of depositing the DSA layer and the step of phase separation are to be considered, and thus these steps are to be performed with relative ease. In addition, the patterning process for forming air gaps in this disclosure is not limited to the embodiments herein, and is applicable to any substrate metal process, for example, the substrate metal process for forming an interconnect layer in back end of line (BEOL), the metal substrate process for forming device regions in front end of line (FEOL), etc.

Referring to FIGS. 11A to 11C, the semiconductor device 200 in accordance with some embodiments in this disclosure includes a bottom ILD layer 11 that is formed with a via feature 13, a glue layer 12 that is disposed on the bottom ILD layer 11, a plurality of metal lines 20 that are disposed on the glue layer 12, and a covering layer 7 that is disposed on the metal lines 20.

The via feature 13 has a top surface that is flush with a top surface of the bottom ILD layer 11, and is aligned with one of the metal lines 20. The glue layer 12 covers the top surface of the via feature 13 and partially covers the top surface of the bottom ILD layer 11, and is configured to serve as adhesive bonding between the bottom ILD layer 11 and the metal lines 20 and adhesive bonding between the via feature 13 and the corresponding metal line 20.

The metal lines 20 extend in an along-line direction Y, and are spaced apart from each other in a cross-line direction X that is perpendicular to the along-line direction Y. The metal lines are spaced apart by a plurality of dielectric structures so that any adjacent two of the metal lines 20 are not in electrical contact with each other. The semiconductor structure 200 further includes a line-cut ridge 40 that is disposed on the bottom ILD layer 11, that extends in the cross-line direction X and that includes a low-k dielectric material. For each of the metal lines 20, the line-cut ridge 40 divides the metal line 20 into metal line segments which are spaced apart from each other in the along-line direction Y, so that the metal line segments are not in electrical contact with each other. Top surfaces of the metal lines 20, the dielectric structure and the line-cut ridge 40 are coplanar, and the covering layer 7 are disposed on the top surfaces of the metal lines 20, the dielectric structures and the line-cut ridge 40.

Each of the dielectric structures includes two polymer blocks 51 that are formed on sidewalls of adjacent two of the metal lines 20 bordering the dielectric structure, and an air gap 6 that is sandwiched between the two polymer blocks 51. The polymer blocks 51 are disposed on the bottom ILD layer 11, and extend from the bottom ILD layer 11 to the covering layer 7. The air gap 6 is bordered by the polymer blocks 51, the line-cut ridge 40, the bottom ILD layer 11 and the covering layer 7. The covering layer 7 covers the air gaps 6 of the dielectric structures. The polymer blocks 51 are derived from one of two different main components forming a BCP. The polymer blocks 51 have widths that are substantially identical, and a pitch of the air gap 6 is substantially identical to any of the widths of the polymer blocks. However, the dimensions of the polymer blocks 51 and the air gap 6 are limited to such, and may vary based on different designs and applications.

To summarize the advantages which have been mentioned above, the semiconductor device 200 including air gaps 6 that are formed by using DSA patterning technique of this disclosure has a relatively low capacity because of the air gaps 6, and the DSA patterning technique is applicable to any other metal substrate, and is relatively easy to realize because a single patterning direction is involved.

In accordance with some embodiments of the present disclosure, a method includes patterning a metal layer on a substrate to form two metal lines spaced apart from each other by a recess, forming a directed self-assembly (DSA) segment in the recess, wherein the DSA segment includes block co-polymer (BCP), performing a phase separation process on the DSA segment to cause two components of the BCP to separate from each other to form a first polymer block and a second polymer block that are aligned next to each other in the recess, and removing the second polymer block to form an air gap that is bordered by the first polymer block and that is located between the metal lines.

In accordance with some embodiments of the present disclosure, forming a DSA segment in the recess includes depositing a DSA layer on the metal lines, wherein the DSA layer includes the BCP and fills into the recess, and removing the DSA layer above top surfaces of the metal lines, wherein a portion of the DSA layer located in the recess remains so as to form the DSA segment.

In accordance with some embodiments of the present disclosure, the DSA layer includes a bi-block polymer, polystyrene-block-polymethylmethacrylate (PS-b-PMMA).

In accordance with some embodiments of the present disclosure, the DSA layer is deposited by one of spin-on coating, spraying, dip coating, and combinations thereof.

In accordance with some embodiments of the present disclosure, performing a phase separation process on the DSA segment includes applying elevated-temperature annealing to the DSA segment.

In accordance with some embodiments of the present disclosure, the first polymer block includes PS and the second polymer block includes PMAA.

In accordance with some embodiments of the present disclosure, in removing the second polymer block, the second polymer block has a high etching selectivity with respect to the first polymer block, so that the second polymer block is selectively etched away to leave the first polymer block remaining.

In accordance with some embodiments of the present disclosure, removing the second polymer block includes performing dry etching to decompose the second polymer block.

In accordance with some embodiments of the present disclosure, in performing dry etching, one of oxygen, carbon oxide and a combination thereof is used as an etching gas.

In accordance with some embodiments of the present disclosure, the method further includes depositing a covering layer over the metal lines and the first polymer block, wherein the covering layer covers an opening of the air gap in the recess.

In accordance with some embodiments of the present disclosure, a method includes forming a metal line pattern on a metal substrate, wherein the metal line patterning includes a plurality of metal lines spaced apart by a plurality of recesses, forming a plurality of directed-self aligned (DSA) segments respectively in the plurality of recesses, wherein the DSA segments includes block co-polymer (BCP), performing a phase separation process on the plurality of DSA segments to form, in each of the plurality of recesses, two first polymer blocks on sidewalls of two of the plurality of metal lines that border the recess, and a second polymer block sandwiched between the two first polymer blocks, and removing, with respect to each of the recesses, the second polymer block so as to form an air gap bordered by the two first polymer blocks.

In accordance with some embodiments of the present disclosure, forming a metal line pattern includes forming a hard mask over the metal substrate, and etching the metal substrate through openings of the hard mask to form the metal line pattern, wherein each of the plurality of metal lines extends in an along-line direction, and is cut in a cross-line direction perpendicular to the along-line direction so that the metal line is divided into two metal line segments.

In accordance with some embodiments of the present disclosure, the method further includes forming a line-end ridge in locations where the plurality of metal lines are cut, wherein the line-end ridge includes a non-conductive material.

In accordance with some embodiments of the present disclosure, forming a line-end ridge includes depositing a sacrificial layer on the mask layer, etching the sacrificial layer to form a pattern that has a gap which encompasses the locations where the plurality of metal lines are cut, depositing a line end layer on the sacrificial layer, wherein the line end layer fills into the gap of the sacrificial layer, and removing the line end layer, the sacrificial layer and the hard mask above top surfaces of the plurality of metal lines, so that a portion of the line end layer left in the gap of the sacrificial layer remains and forms the line-end ridge.

In accordance with some embodiments of the present disclosure, the DSA layer includes one of polystyrene-block-polymethylmethacrylate (PS-b-PMMA), polyethyleneoxide block-polyisoprene (PEO-b-PI), polyethyleneoxide-block polybutadiene (PEO-b-PBD), polyethyleneoxide-block polystyrene (PEO-b-PS), polyethyleneoxide-block polymethylmethacrylate (PEO-b-PMMA), polyethyleneoxide-block-polyethylethylene (PEO-b-PEE), polystyrene-block-polyvinylpyridine (PS-b-PVP), polystyrene-block-polyisoprene (PS-b-PI), polystyrene-block polybutadiene (PS-b-PBD), polystyrene-block-polyferroce nyldimethylsilane (PS-b-PFS), polybutadiene-block polyvinylpyridine (PBD-b-PVP), polyisoprene block-polymethylmethacrylate (PI-b-PMMA), and combinations thereof.

In accordance with some embodiments of the present disclosure, the method further includes depositing a covering layer over the metal lines and the two first polymer blocks, wherein the covering layer covers openings of the air gaps in the plurality of recesses, respectively.

In accordance with some embodiments of the present disclosure, the covering layer includes one of a silicon oxide (SiO₂), silicon nitride (SiN), silicon oxynitride (SiON), silicon carbide (SiC) and combinations thereof.

In accordance with some embodiments of the present disclosure, a semiconductor device includes a metal substrate that is formed with two metal lines that are spaced apart from each other, and a dielectric structure that is disposed between the two metal lines to electrically isolate the two metal lines, wherein the dielectric structure includes two polymer blocks that are respectively formed on sidewalls of the two metal lines bordering the dielectric structure, and an air gap that is sandwiched between the two polymer blocks.

In accordance with some embodiments of the present disclosure, the metal substrate includes an interlayer dielectric (ILD) layer, and a glue layer that is disposed on the ILD layer, wherein the two metal lines are directly disposed on the glue layer and the two polymer are directly disposed on the ILD layer..

In accordance with some embodiments of the present disclosure, the semiconductor device further includes a covering layer that is disposed on the two metal lines and the two polymer blocks, and that covers the air gap.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
patterning a metal layer on a substrate to form two metal lines (20) spaced apart from each other by a recess;
forming a directed self-assembly (DSA) segment (50) in the recess, the DSA segment (50) including block co-polymer (BCP);
performing a phase separation process on the DSA segment (50) to cause two components of the BCP to separate from each other to form a first polymer block (51) and a second polymer block (52) that are aligned next to each other in the recess; and
removing the second polymer block (52) to form an air gap (6) that is bordered by the first polymer block (51) and that is located between the metal lines (20).

2. The method as claimed in claim 1, wherein forming a DSA segment in the recess includes:
depositing a DSA layer on the metal lines, the DSA layer including the BCP and filling into the recess; and
removing the DSA layer above top surfaces of the metal lines, a portion of the DSA layer located in the recess remaining so as to form the DSA segment.

3. The method as claimed in claim 2, wherein the DSA layer includes a bi-block polymer, polystyrene-block-polymethylmethacrylate (PS-b-PMMA).

4. The method as claimed in claim 2, wherein the DSA layer is deposited by one of spin-on coating, spraying, dip coating, and combinations thereof.

5. The method as claimed in claim 1, wherein performing a phase separation process on the DSA segment includes applying elevated-temperature annealing to the DSA segment.

6. The method as claimed in claim 1, wherein the first polymer block includes PS and the second polymer block includes PMAA.

7. The method as claimed in claim 1, wherein in removing the second polymer block, the second polymer block has a high etching selectivity with respect to the first polymer block, so that the second polymer block is selectively etched to leave the first polymer block remaining.

8. The method as claimed in claim 7, wherein removing the second polymer block includes performing dry etching to decompose the second polymer block.

9. The method as claimed in claim 8, wherein in performing dry etching, one of oxygen, carbon oxide and a combination thereof is used as an etching gas.

10. The method as claimed in claim 1, further comprising depositing a covering layer over the metal lines and the first polymer block, the covering layer covering an opening of the air gap in the recess.

11. A method comprising:
forming a metal line pattern on a metal substrate, the metal line patterning including a plurality of metal lines spaced apart by a plurality of recesses;
forming a plurality of directed-self aligned (DSA) segments respectively in the plurality of recesses, the DSA segments including block co-polymer (BCP);
performing a phase separation process on the plurality of DSA segments to form, in each of the plurality of recesses, two first polymer blocks on sidewalls of two of the plurality of metal lines that border the recess, and a second polymer block sandwiched between the two first polymer blocks;
removing, with respect to each of the recesses, the second polymer block so as to form an air gap bordered by the two first polymer blocks.

12. The method as claimed in claim 11, wherein forming a metal line pattern includes:
forming a hard mask over the metal substrate; and
etching the metal substrate through openings of the hard mask to form the metal line pattern;
wherein each of the plurality of metal lines extends in an along-line direction, and is cut in a cross-line direction perpendicular to the along-line direction so that the metal line is divided into two metal line segments.

13. The method as claimed in claim 12, further comprising forming a line-end ridge in locations where the plurality of metal lines are cut, the line-end ridge including a non-conductive material.

14. The method as claimed in claim 13, wherein forming a line-end ridge includes:
depositing a sacrificial layer on the mask layer;
etching the sacrificial layer to form a pattern that has a gap which encompasses the locations where the plurality of metal lines are cut;
depositing a line end layer on the sacrificial layer, the line end layer filling into the gap of the sacrificial layer; and
removing the line end layer, the sacrificial layer and the hard mask above top surfaces of the plurality of metal lines, so that a portion of the line end layer left in the gap of the sacrificial layer remains and forms the line-end ridge.

15. The method as claimed in claim 11, wherein the DSA layer includes one of polystyrene-block-polymethylmethacrylate (PS-b-PMMA), polyethyleneoxide block-polyisoprene (PEO-b-PI), polyethyleneoxide-block polybutadiene (PEO-b-PBD), polyethyleneoxide-block polystyrene (PEO-b-PS), polyethyleneoxide-block polymethylmethacrylate (PEO-b-PMMA), polyethyleneoxide-block-polyethylethylene (PEO-b-PEE), polystyrene-block-polyvinylpyridine (PS-b-PVP), polystyrene-block-polyisoprene (PS-b-PI), polystyrene-block polybutadiene (PS-b-PBD), polystyrene-block-polyferroce nyldimethylsilane (PS-b-PFS), polybutadiene-block polyvinylpyridine (PBD-b-PVP), polyisoprene block-polymethylmethacrylate (PI-b-PMMA), and combinations thereof.

16. The method as claimed in claim 11, further comprising depositing a covering layer over the metal lines and the two first polymer blocks, the covering layer covering openings of the air gaps in the plurality of recesses, respectively.

17. The method as claimed in claim 16, wherein the covering layer includes one of a silicon oxide (SiO₂), silicon nitride (SiN), silicon oxynitride (SiON), silicon carbide (SiC) and combinations thereof.

18. A semiconductor device comprising:
a metal substrate that is formed with two metal lines that are spaced apart from each other; and
a dielectric structure that is disposed between the two metal lines to electrically isolate the two metal lines;
wherein the dielectric structure includes two polymer blocks that are respectively formed on sidewalls of the two metal lines bordering the dielectric structure, and an air gap that is sandwiched between the two polymer blocks.

19. The semiconductor device as claimed in claim 18, wherein the metal substrate includes an interlayer dielectric (ILD) layer, and a glue layer that is disposed on the ILD layer, the two metal lines being directly disposed on the glue layer and the two polymer being directly disposed on the ILD layer.

20. The semiconductor device as claimed in claim 18, further comprising a covering layer that is disposed on the two metal lines and the two polymer blocks, and that covers the air gap.
